(19) United States
(12) Patent Application Publication
(10) Pub. No.: US 2009/0237312 A1
(43) Pub. Date: Sep. 24, 2009

(54) Antenna

(76) Inventors: Edward A. Schober, Haddon Heights, NJ (US); James W. Pollock, Mount Laurel, NJ (US)

Correspondence Address: Edward A. Schober, 402 10th Avenue, Haddon Heights, NJ, 08035, US

(21) Appl. No.: 12/381,602

(22) Filed: Mar. 13, 2009

Related U.S. Application Data
(60) Provisional application No. 61/070,609, filed on Mar. 24, 2008.

(51) Int. Cl. G01R 29/08

(52) U.S. Cl. 343/703

(57) ABSTRACT

The present invention involves a transmitting antenna system that includes at least one high impedance transmitting antenna element, a voltage sampling device, and monitoring equipment. The antenna element(s) each have a driving point that receives radio signals from a radio frequency power source. A voltage sampling device measures the voltage magnitude and phase of the radio signal at the driving point of each antenna elements. A voltage sampling device is physically located near each of the antenna elements being monitored and each voltage sampling device transmits information relating to phase and voltage magnitude to the monitoring equipment that is located remote of at least one of the antenna elements. The monitoring equipment can compare the phase and voltage magnitude of each of the antenna elements in the transmitting antenna system to a pre-determined set of values and/or to the values of the other antenna element(s) in the transmitting antenna system.

### CROSS-REFERENCE TO RELATED APPLICATIONS

The present application claims priority to U.S. Provisional Application No. 61/070,609 filed on Mar. 13, 2008.

### BACKGROUND OF THE INVENTION

A. Field of Endeavor

The present invention relates generally to an improved instrumentation system for phased array transmitting antennas and, more particularly, to a sampling apparatus for voltage fed phased array antennas.

B. Background Information

Generally speaking, an antenna is a transducer designed to transmit or receive electromagnetic waves. In other words, antennas convert electromagnetic waves into electrical currents, and vice versa. Antennas are used in well-known applications, such as radio and television broadcasting, point-to-point radio communication, wireless LAN, radar, and space exploration. Antennas work in a number of environments, ranging from the earth's atmosphere to outer space, but can also be operated under water or even through soil and rock at certain frequencies for short distances.

Physically, an antenna that transmits a signal is usually an arrangement of conductors that generate a radiating electromagnet field in response to an applied alternating voltage and the associated alternating electric current. A receiving antenna is a similar set-up that can be placed in an electromagnetic field so that the field will induce an alternating current in the antenna and a voltage between its terminals. Some antenna devices just adapt the free space to another type of antenna.

Radio transmitting antennas may consist of multiple elements which are individually driven from a radio frequency power source by transmission lines and matching networks in order to achieve specific radiation distribution patterns, with maximum signal strength directed towards the desired directions and the signal strength limited in other directions. The signal limitation in some directions may be for the purpose of reducing, if not eliminating, interference with other stations, or to improve the power efficiency of the station by directing the signal in primarily the desired directions.

The radiation distribution patterns of directional antennas are established by providing the radio frequency power to the antenna elements in a specific ratio of power and signal phase. To maintain the radiation distribution pattern, it is necessary to maintain the individual power and phase relationships between the elements within a specified tolerance.

In situations when the electrical input impedance of an element of a directional antenna is low (e.g., less than two (2) to three (3) times the characteristic impedance of the transmission line feeding the antenna), it is desirable to monitor the current magnitude and phase of the rf signal applied to each element because disruptive variations in the antenna characteristics will substantially vary the current in the antenna. For low electrical impedance antennas, monitoring the electrical input impedance using a current sample, such as a current transformer is quite satisfactory.

In situations when the electrical input impedance of a directional antenna is high (e.g., three (3) or more times the characteristic impedance of the transmission line feeding the antenna), it is desirable to monitor the voltage of each element. Monitoring the voltage of each element in such a system is desirable since it has been found that the magnitude of the current and phase of the current of a high do not correspond well with changes in the directive characteristics of the antenna. In other words, disruptions in the pattern do not have a direct relationship with the monitored current at the antenna drive point for elements with high electrical input impedance.

Currently, the method often used to monitor the element radiation for antennas with high electrical input impedance includes installing a magnetic loop on the radiating element at the point of maximum current in the element. This method, however, has shortcomings because it requires that the sample signal be transferred across a voltage feed point that has high voltage. Additional shortcomings exist in the current methods because the magnetic loops are physically located on the antenna element itself, making them subject to damage from weather and lightning. In addition, the magnetic loops are difficult to maintain because of their often elevated location on an element which may provide rf hazards during operation. And, for antennas operating at several megaHertz and lower, servicing the loops often entails climbing to unsafe heights.

Since radio frequency directional antennas can be large, the individual antenna elements are physically separated, hazardous to approach, and mounted outdoors, and because the each of the elements must be individually monitored, it is generally not practical to install the monitoring equipment adjacent to the element feed point. Furthermore, it is extremely difficult, if not impossible, to install monitoring equipment at all of the feed points.

A current transformer can be used with an element of low operating impedance by simply connecting it between the antenna coupler and the element feed point. The sample can be directly connected to a coaxial transmission line that will transfer the sampled information about that tower to the antenna monitoring equipment, which can be mounted at a convenient distance from the antenna element.

For reasons listed above, it is impractical to use a current transformer to sample the antenna element information for high impedance feed point elements. Without other circuit elements, a capacitive divider cannot feed a transmission line directly to the monitoring equipment.

The above-listed problems create situations where it is difficult to install a system for properly monitoring antenna elements in directional antennas that operate with high electrical input impedance.

Accordingly, it is desirable to create a device that effectively monitors the elements of directional antennas while eliminating some or all of the above-noted shortcomings and physical difficulties found currently in the art.

### DISCLOSURE OF THE INVENTION

One aspect of the present invention includes a transmitting antenna system that has at least one antenna element, a radio frequency power source, a voltage sampling device, and monitoring equipment. The antenna element(s) have a driving point where the radio signal from the radio frequency power source is received. The antenna element is a high impedance transmitting antenna and the driving point is a high impendence point. The radio signal has a phase and a voltage magnitude. The voltage sampling device measures the voltage magnitude and the phase at the driving point of the at least one antenna element. The voltage sampling device is physically located near one of the at least one antenna elements and is electrically connected to a monitoring equipment that is remote of at least one of the at least one antenna element.

According to another aspect of the present invention, the monitoring equipment compares the phase and voltage magnitude to pre-determined values.

According to a further aspect of the present invention, there are at least two antenna elements that form an array of antenna elements.

According an even further aspect of the present invention, the monitoring equipment is capable of comparing the phase and voltage magnitude of each antenna element to which the monitoring equipment is connected to at least one other antenna element to which the monitoring equipment is also electrically connected.

The advantage of the present invention will become known to one of skill in the art in light of the drawings and description provided below.

### BRIEF DESCRIPTION OF THE PROVIDED VIEW(S) OF THE DRAWING(S)

FIG. 1 depicts a diagrammatic view of one embodiment of the transmitting antenna system of the present invention; and

FIG. 2 depicts a diagrammatic view of a voltage sampling apparatus of the present invention.

### DETAILED DESCRIPTION OF THE INVENTION

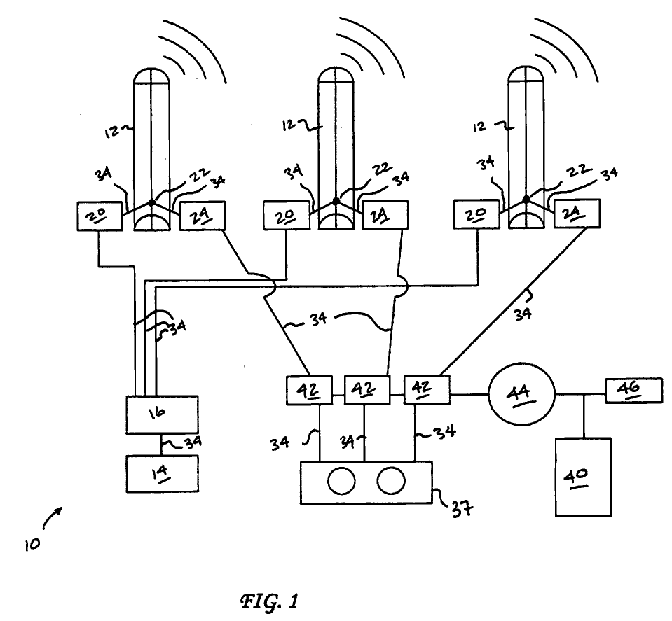

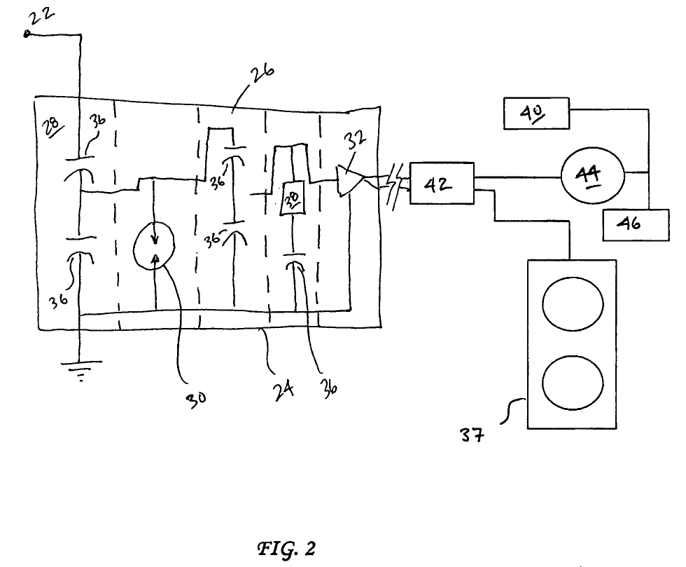

Referring now to FIGS. 1 and 2, a transmitting antenna system of the present invention is generally referred to as numeral 10. The transmitting antenna system 10 includes one or more antenna element(s) 12, a radio frequency power source 14, a device 16 for controlling the distribution of radio signals to the antenna element couplers 20, and an antenna element coupler 20 for each antenna element 12. Each antenna element coupler 20 is electrically connected to the driving point 22 of the antenna 12 to which it antenna element coupler 20 is coupled. A voltage sampling device 24 is also electrically coupled to the driving point 22 of each antenna element 12. The voltage sampling device 24 includes a low sensitivity voltage divider 26, a high voltage divider 28, an (optional) gas discharge over voltage protector 30, and a voltage signal amplifier 32. The voltage sampling device 24 measures the voltage magnitude and phase at the driving point 22 of the antenna element 12.

Referring now to FIG. 1, the antenna element 12 is an electrically conductive rod, a self-supporting or guyed tower, or any other device known to one of skill in the art to transmit or receive a radio signal. The antenna element 12 includes driving point into which radio signals from an rf power source 14 are fed. The radio signals are transferred from the driving point 22 to the body of the antenna element 21 where they are emitted. In the present invention, the antenna is intended for use as a high electrical input impedance antenna. In high electrical input impedance antennas, the driving point 22 is also the high impedance point. Although the voltage sampling device 24 of the present invention can be used in conjunction with a single antenna element 12, it is often desirable to use the voltage sampling device 24 in conjunction with any number of antenna elements 12 working together to simultaneously transmit the same radio signal. Therefore, the voltage sampling device 24 of the present invention can be used with more than one antenna element 12 (e.g., two, three, four, five, six, or more) such that the system can comprise an array of antenna elements 12.

In order to transmit a radio signal via an antenna element 12, the desired modulating signal (e.g., an audio signal) must be submitted to a radio frequency power source 14 by any known means. For example, one of skill in the art could use an rf transmitter as a suitable power source for transmitting an audio signal. The radio frequency power source 14 then passes the radio signal to a device 16 that controls the distribution of radio signals via suitable means, such as a transmission line 34. The device 16, in some applications, can be called a phaser. For example, one of skill in the art could use either a coaxial cable or an open wire to transmit the radio signal from the radio frequency power source 14 to the device 16. The actual device 16 can vary widely and consists of electrical components that adjust the phase and voltage of the radio signal for proper transfer to the individual antenna elements 12. The actual device 16 depends on the application and is subject to the real world needs of the transmitting antenna system 10, which depend on factors such as desired strength of the signal, the intended direction of the signal, and the suppression of signals in certain directions to, for example, avoid interference with the signal of separate and distinct antenna systems.

Once the device 16 has properly adjusted the radio signal to the appropriate voltage and phase for the individual antenna elements 12, the radio signal is transmitted via appropriate means (e.g., transmission lines 34) to antenna element coupler(s) 20. As shown in FIG. 1, in transmitting antenna systems 10 employing multiple antenna elements 12, the device 16 individualizes the radio signal for each individual antenna element 12 such that each antenna element 12 will transmit the same signal, varying only in phase and power. As stated above, any appropriate transmission line, including but not limited to an open wire or a coaxial cable, can be employed for transmitting the radio signal(s) from the device 16 to the antenna element couplers 20.

Continuing to refer to FIG. 1, the antenna element couplers 20 are generally located adjacent the antenna element 12 to which it is coupled. The antenna element coupler(s) 20 receive the signal from the radio frequency power source 14 (via the device 16) and convert the electrical impedance of the transmission lines 34 to the actual impedance presented by the antenna element 12 for the desired signal. The transmitted signal is then delivered to the driving point 22 of the antenna element 12 and the radio signal is transmitted by the antenna. The signals from the various antenna elements 12 are combined in space to provide the desired overall directionality, or other characteristics, established by the design of the actual transmitting antenna system 10.

Referring now to FIGS. 1 and 2, a voltage sampling device 24 is located close to each antenna element 12. Although shown diagrammatically located adjacent the antenna element 12 in FIG. 1, the voltage sampling device 24 should be physically located close to the antenna element 12. For example, in some applications, it may be preferable to house the voltage sampling device 24 in the same housing (not shown) as an antenna element coupler 20.

The voltage sampling device 24 is connected to the driving point 22 of the antenna element 12 via a suitable transmission line 34. Although the connection between the driving point 22 and the voltage sampling device 24 is shown in FIG. 1 as being a separate connection than the connection between the driving point 22 of the antenna element 12 and the antenna element coupler 20, the same transmission line 34 can be used for both connections.

Referring now to FIG. 2, the voltage sampling device 24 measures the voltage magnitude and phase at the driving point 22 (i.e., at the high impedance point, where the radio signal is supplied by the radio frequency power source) of the antenna element 12. The voltage sampling device 24 includes a high voltage divider 28 and a low voltage divider 26. Both voltage dividers 26,28 include a series of at least two (2) connected capacitors 36. The voltage division ratio of the input signal compared to the signal transmitted to the monitoring equipment 37 is typically from several hundred to several thousand to one. One side of the voltage divider 26,28 is connected to the circuit being monitored, the other side is grounded. The voltage dividers 26,28, also known as a potential dividers, are simple linear circuits that produce an output voltage that is a fraction of the input voltage. Voltage division refers to the partitioning of a voltage among the components of the voltage divider 26,28. By having a high and a low voltage divider 26,28, the voltage sampling device of the present invention permits the utilization of available capacitor 36 technologies that both withstand the high voltages involved, and provide the required values, stability and tolerances. In some embodiments, the voltage divider 28 is connected on one end to ground, and the other end to an intermediate point on the high voltage divider 26.

An electromagnetic relay 38 or other switching device, such as a transistor, may optionally be utilized. If used, it is connected to the second voltage divider to change the voltage division ratio between two or more ratios. Such an electromagnetic relay is controlled by circuitry in the voltage sampling device 24 that detects the presence of the low frequency control signal on the DC power source 42 supplied through the sample transmission line 34 and signal injector 42.

A gas discharge over voltage protector 44 can also, optionally be utilized in the voltage sampling device. The gas discharge over voltage protector 30, or similar device, can be utilized to prevent the voltage sampling device 24 from being destroyed in, for example, the event of a lightning strikes or static discharge. The gas discharge over voltage protector 30 is positioned in the voltage sampling device 24 such that the signal amplifier 32 is protected from a surge.

The voltage sampling device 24 further has a voltage signal amplifier 32. After the voltage has been reduced by the voltage dividers 26,28, the voltage is then amplified by the voltage signal amplifier 32. A suitable voltage signal amplifier 32 can be chosen by the designer of the voltage sampling device 24 based on the exact needs of the transmitting antenna system 10 being monitored. The voltage signal amplifier 32 can be chosen from any known signal amplifier known to those of skill in the art that are suitable for feeding a coaxial cable (or other suitable transmission line 34) connected to monitoring equipment 37.

A DC power source 40 is conveniently located near the monitoring equipment 37 and is used to provide operating power for the voltage signal amplifier 32 within the voltage sampling device 24. The DC power source 40 will provide, typically, 28 V for this purpose.

A control module 44 and switch 46 can be optionally provided to control the voltage division ratio of the voltage sampling device 24. When controlled by a switch 46 or other electrical contacting device, it will impress a low frequency (e.g., several orders of magnitude lower than the radio frequency) control signal upon the DC power to the voltage signal amplifier 32. This low frequency signal is optionally detected by circuitry within the voltage signal amplifier 32 and used to control an electromagnetic relay 38 that adjusts the voltage division ratio between discrete ratios as needed to monitor the antenna element(s) 12 for different modes of operation. During the different modes of operation, the parameters of power, voltage, and phase of the antenna element(s) 12 are changed for, e.g., different transmission goals or testing.

The injector 42 provides a facility for simultaneously feeding DC power from the DC power source 40 and, optionally, the low frequency control signal from the control module 44 to the voltage sampling device 24, while simultaneously separating the radio frequency sampling signal from the voltage sampling device 24 to provide an input to the monitoring equipment 37.

Referring to FIGS. 1 and 2, the monitoring equipment 37 is connected to each of the voltage sampling devices 24 associated with each of the antenna elements 12. The monitoring equipment 37 receives the phases and voltage magnitude from each of the voltage sampling devices 24 in the transmitting antenna system 10. The monitoring equipment 37 utilizes known processing equipment and displays to provide end-user-appropriate output signals. Preferably, the output signals compare each of the phase and voltage magnitude values provided by each of the voltage sampling devices 24 to either or both of 1) a pre-determined value and/or 2) the values of the other voltage sampling devices 24.

The monitoring equipment 37 can be located anywhere, provided that the monitoring equipment 37 is electrically connected (e.g., via appropriate transmission lines 34) to each of the voltage sampling devices 24 that the monitoring equipment 37 is monitoring. For example, the monitoring equipment 37 could be located near one of the antenna elements 12 or remote of all of the antenna elements 12. In addition, the monitoring equipment 37 can be located at a safe height (e.g., ground level) so that, for example, a technician only has to travel to a single location that is at a safe height to monitor any number of antenna elements 12 working together in a transmitting antenna system 10.

In operation, a user provides a desired radio signal to the radio frequency power source 14. The radio frequency power source 14 then transmits the radio signal to the driving point 22 of one or more antenna elements 12 (via a device and antenna coupler(s) 20 and transmission lines 34). The radio signal is then transmitted out through the antenna element(s) 12. During transmission of the radio signals, a voltage sampling device 24 at each antenna element 12 monitors the phase and voltage magnitude of the radio signal being transmitted. The voltage sampling device 24 relays this information to the monitoring equipment 37 which relates the information to 1) a baseline phase and voltage magnitude and/or 2) the phase and voltage magnitude of the other antenna elements in the transmitting antenna system. The outputted information is easily viewed at a single and, preferably, convenient and safe location. The outputted information is then used to determine whether the transmitting antenna system 10 is operating as expected, or whether the transmitting antenna system 10 is in need of service.

It will be appreciated to one of skill in the art that modifications can be made to the above-described transmitting antenna system and voltage sampling device without departing from the spirit and scope of the present invention.

What is claimed is:

1. A transmitting antenna system, comprising:
at least one antenna element having a driving point, the driving point receiving a radio signal from a radio frequency power source, where the radio signal has a phase and a voltage magnitude;
a voltage sampling device that measures the voltage magnitude and the phase at the driving point of the at least one antenna element;
wherein the antenna element is a high impedance transmitting antenna and the driving point is a high impendence point; and
wherein the voltage sampling device is physically located near one of the at least one antenna elements; and
wherein the voltage sampling device is electrically connected to a monitoring equipment that remote of at least one of the at least one antenna element.

2. The transmitting antenna system of claim 1 wherein the monitoring equipment compares the phase and voltage magnitude to pre-determined values.

3. The transmitting antenna system of claim 1 wherein there are at least two antenna elements.

4. The transmitting antenna system of claim 3, wherein the monitoring equipment is electrically connected to the at least two of the at least two antenna elements.

5. The transmitting antenna system of claim 4, wherein the monitoring equipment compares the phase and voltage magnitude of each antenna element to which the monitoring equipment is connected to at least one other antenna element to which the monitoring equipment is electrically connected.

6. The transmitting antenna system of claim 4, wherein the monitoring equipment compares the phase and voltage magnitude of the at least two antenna elements to pre-determined values.

7. The transmitting antenna system of claim 3, wherein the monitoring equipment is located remote of at least one of the at least two antenna elements.

8. The transmitting antenna system of claim 3, wherein the monitoring equipment is located remote of all of the at least two antenna elements.

9. The transmitting antenna system of claim 1, wherein the monitoring equipment is located at ground level.

10. The transmitting antenna system of claim 1, wherein the voltage sampling device includes a high voltage divider and a low sensitivity voltage divider.

11. The transmitting antenna system of claim 1, wherein the voltage sampling device includes a voltage signal amplifier.

12. The transmitting antenna system of claim 1, wherein the voltage sampling device includes a gas discharge over voltage protector that protects the voltage signal amplifier from a surge.

13. The transmitting antenna system of claim 3, wherein the voltage sampling device has a first pre-determined sensitivity and a second pre-determined sensitivity and a control module is in electrical communication with the voltage sampling device such that the control module can change the voltage sampling device from the first pre-determined sensitivity to the second pre-determined sensitivity, and vice versa.

14. The transmitting antenna system of claim 13, wherein a switch is coupled to the control module.

15. The transmitting antenna system of claim 14, wherein the switch enables a user to manually change the sensitivity of the voltage sampling device from the first pre-determined sensitivity to the second pre-determined sensitivity, and vice versa.

16. The transmitting antenna system of claim 13, wherein the control module can automatically change the sensitivity of the voltage sampling device from the first pre-determined sensitivity to the second pre-determined sensitivity, and vice versa, upon a pre-determined set of conditions being met.

17. The transmitting, antenna system of claim 1 where a sampled voltage is divided in a circuit comprising a series connection of two or more circuit elements having a first end and a second end, the first end of which is connected to ground and the second end of which is connected to the voltage to sampled.

18. The transmitting antenna system of claim 17 where the series connection of two or more circuit elements comprising a voltage divider includes electrical capacitors.
